(19) United States
(12) Patent Application Publication
(10) Pub. No.: US 2007/0096249 A1
(43) Pub. Date: May 3, 2007

(54) Three-dimensionally integrated electronic assembly

(76) Inventors: Heiko Roeper, Radeberg (DE); Johannes Hankofer, Aiterhofen (DE); Harry Hedler, Germering (DE); Armin Kohlhase, Neubiberg (DE)

Correspondence Address: SLATER & MATSIL LLP, 17950 PRESTON ROAD, SUITE 1000, DALLAS, TX, 75252, US

(21) Appl. No.: 11/513,827

(22) Filed: Aug. 31, 2006

(30) Foreign Application Priority Data
Aug. 31, 2005 (DE) 10 2005 041 452.4

(51) Int. Cl. H01L 29/00

(52) U.S. Cl. 257/528

(57) ABSTRACT

A three-dimensionally integrated electronic assembly includes a substrate that includes active circuitry formed therein. At least one electronic component (e.g., an integrated circuit chip, active component, passive component, active assembly, and/or passive assembly) is mounted on the substrate. At least one redistribution connection is disposed between the substrate and at least one electronic component. Each electronic component is electrically coupled to the substrate and/or another electronic component mounted on the substrate by means of the redistribution connection.

This application claims priority to German Patent Application 10 2005 041 452.4, which was filed Aug. 31, 2005 and is incorporated herein by reference.

### TECHNICAL FIELD

The invention relates to a three-dimensionally integrated electronic assembly.

### BACKGROUND

With advancing miniaturization, electronic assemblies are performing increasingly more complex functions. Typical areas of application are mobile radio devices, PDAs, cameras, clock computer and mobile data storage devices. In these devices it is typically necessary to integrate a plurality of chips, SMD (surface mount device) components and further elements in a small space.

Chips and components are mounted, for example, on a PCB (printed circuit board), ceramic substrate or silicon substrate. Chips having a small area requirement for mounting can be fabricated as WLP (wafer level package). Multichip arrangements are produced as MCM (multi-chip module) in IC (integrated circuit) packages (e.g., SOP (small outline package) or DIP (dual in-line package)), as BGA (ball grid array) package or as COB (chip-on-board) with globe top passivation. One possibility for the vertical arrangement of a plurality of chips consists in mounting as stacked chips or as second level assembly on WLP.

By way of example, German Patent Application 101 53 609 C2, and corresponding U.S. Pat. No. 6,714,418 B2, both of which applications are incorporated herein by reference, describe a method for producing an electronic component with a plurality of chips that are stacked one above another and are contact-connected to one another.

U.S. Pat. No. 6,185,124 B1, which is incorporated herein by reference, presents a memory assembly with an arrangement comprising a chip and a passive component in a common circuit housing.

A multichip arrangement is revealed in German Patent Application 199 05 220 A1, which is incorporated herein by reference. This document describes, for example, a triple chip stack on a chip carrier, in which smaller chips, in each case are fixed on the relevant chip situated underneath by means of adhesive bonding. Here electrical contact is made between the chips and the chip carrier by means of wire bridges, the entire chip arrangement on the chip carrier being encapsulated with an encapsulant.

It has been shown that considerable mounting and packaging costs arise in the case of integrated electronic assemblies, that is to say in the case of assemblies in which a plurality of different component and packaging types are combined with one another. Moreover, there are stringent requirements with regard to reducing the area and space requirement. A specific problem on account of the continually increasing clock frequencies arises as a result of, in part, considerable signal paths or signal paths of different lengths with the associated signal propagation time differences or else the interference radiation.

One possibility that has become known in the meantime for shortening the signal paths consists in the use of pillar-type interconnect elements at the wafer level.

### SUMMARY OF THE INVENTION

In one aspect, the invention specifies an arrangement for an integrated electronic assembly that results in a significant reduction of the mounting and packaging costs and of the area and space requirement in conjunction with a simultaneous reduction of the signal paths, flexible package pinout and 3-D integration.

This is achieved by virtue of the fact that the substrate is an integrated active electronic circuit structure including a semiconductor chip at least partly singulated or in the wafer assemblage, a semiconductor wafer, a part of a semiconductor wafer or a plurality of semiconductor wafers mounted one on top of another as second level assembly, a circuit structure on a film or fabric basis and/or on a basis of other inorganic, organic or combined materials with integrated active electronic circuit structures embedded, printed on or applied and/or introduced by other methods. A plane 1 is formed. Redistribution lines, a redistribution layer and/or further interconnects and areas are arranged on plane 1 for wiring (hereinafter RDL) by means of which one or a plurality of additional chips, active and/or passive components, assemblies or parts thereof are connected and/or contact-connected, forming at least one further plane (plane 2) or a plurality of planes 2 . . . n.

In another aspect of the invention, one or a plurality of additional planes are provided with RDL, these being contact-connected among one another and/or to the RDL/RDLs of plane 1, to the substrate, chips, active and/or passive components or assemblies.

The chip or chips, active and/or passive components or assemblies may be mounted and/or electrically contact-connected on the respective RDL/RDLs by bonding, adhesive bonding, welding and/or soldering, the electrical contact-connection being realized, inter alia, by means of bumps (e.g., elastomer bumps), electrically conductive adhesive-bonding, welding and solder connections and also wire bridges.

In one preferred refinement of the invention, the RDL/RDLs is/are formed in multilayer fashion in at least one of the planes and is/are provided with plated-through holes between at least one of the layers with other layers and/or planes, to the substrate and/or one or a plurality of chips, active and/or passive components or assemblies, it being possible for the RDL to have planes for ground, shield, supply voltage and/or interconnects. The RDL may be formed as a waveguide (microstrip and stripline) in radio frequency applications.

A simplification of the electrical contact-connection and a shortening of interconnects are achieved if the RDL is led around the edges of substrate and/or chips, active and/or passive components or assemblies and/or over the surface of additional chips, active and/or passive components or assemblies and/or, if appropriate, is embodied bilaterally or multilaterally on the front side and rear side of the substrate and/or chips, active and/or passive components or assemblies. Furthermore, plated-through holes in the substrate, chips and/or other components may produce a connection of front side and rear side. Chips, active and/or passive components or assemblies may be arranged on the substrate top side, substrate rear side or on both sides of the substrate.

A further development according to the invention is characterized by the fact that at least one partial region of at least one or a plurality of planes is planarized with a polymer or the like and/or by material removal. Height differences caused by chips, components and interconnects, for example, are thereby compensated for, one or a plurality of additional planes with RDL, chips, active and/or passive components or assemblies being able to be applied on the polymer or the planarized area, if appropriate with application of further planarization steps.

In continuation it is provided that the active and/or passive components or assemblies are, or contain packaged and/or mounted chips, SMD components, other resistance elements, capacitors, inductances, diodes, transistors, electrical, electronic, magnetic, electromagnetic, optical or micromechanical components, optocouplers or RF couplers or antenna elements, sensors, actuators, operating and indication elements, elements for energy storage and/or conversion, heat distributors or cooling elements, contact pins, contact sockets and/or contact areas or other connections, force-locking and/or positively locking fixing or connecting elements, etc.

In one refinement of the invention, one or a plurality of active and/or passive components or elements and/or circuit structures using thin film or thick film technology are applied and/or fabricated under, on and/or within at least one RDL, the substrate, chips, active or passive components or assemblies or at least one planarization layer and/or are connected to at least one RDL, the substrate, chips, active or passive components or assemblies.

In further continuation of the invention, the three-dimensionally integrated electronic assembly may be completely or partially provided with an independent housing and/or be provided or enveloped with an encapsulant, coating, covering, passivation, a lacquer, label and/or an inscription, thereby realizing, at least in part, the function of a housing such as, for example, protection of the assembly from mechanical and electrical effects and also identification. The three-dimensionally integrated electronic assembly may be embodied as an independent device with integrated operating and indication elements and/or be provided with contact pins, contact sockets, contact areas and/or contact bumps, electrical, electronic, magnetic, electromagnetic, optical, thermal or mechanical couplers for external connection, which are mounted in or on the assembly.

In other aspects, the invention provides a method for producing a three-dimensionally integrated electronic assembly, by virtue of the fact that the fabrication of the substrate with integrated electronic circuit structures, the mounting of additional chips, active and/or passive components or assemblies, RDL and thin-film and/or thick-film process steps for fabricating additional active and/or passive components or elements and/or circuit structures, the planarization, the encapsulation, the coating or other packaging, the testing and/or the identification are effected partly or completely in the wafer assemblage. Singulation of the three-dimensionally integrated electronic assemblies contained in the wafer assemblage can be subsequently carried out by sawing as required.

In one refinement of the method, all or at least a plurality of the above-mentioned method steps are performed.

### BRIEF DESCRIPTION OF THE DRAWINGS

The invention will be explained in more detail below using an exemplary embodiment. In the associated drawings:

FIG. 1 shows a sectional illustration of a three-dimensionally integrated electronic assembly according to the invention on a wafer with additional chips and SMD components mounted on an RDL;

FIG. 2 shows a sectional illustration of an embodiment variant with a chip that is electrically connected to the wafer by means of wire bridges and on which an additional element is mounted;

FIG. 3 shows a chip stack arrangement on a wafer with multilayer RDL and with additional RDL between the chips;

FIG. 4 shows a three-dimensionally integrated electronic assembly with a multilayer RDL provided with plated-through holes;

FIG. 5 shows a three-dimensionally integrated electronic assembly on a through-plated chip with bilateral, multilayer RDL, with mounted chips and SMD components;

FIG. 6 shows a three-dimensionally integrated electronic assembly that is multiply planarized with polymer layers; and

FIG. 7 shows an example of chip arrangements constructed on a wafer with RDL and additional components.

The following list of reference symbols can be used in conjunction with the figures:

| | |
|---|---|
| 1 | Substrate/wafer |
| 2 | Chip |
| 3 | Electrical connection |
| 4 | Die attach/adhesive film |
| 5 | Molding composition |
| 6 | SMD component |
| 7 | Bonding pad/contact areas |
| 8 | RDL |
| 9 | Insulator |
| 10 | RDL plated-through hole |
| 11 | Bonding connection/wire bridge |
| 12 | Component/additional element |
| 13 | Connecting layer |
| 14 | Planarization/polymer |
| 15 | Bump |
| 16 | Separating trench |
| 17 | BGA component |
| 18 | Encapsulant/housing |
| 19 | PCB |
| 20 | Contact bumps |
| 21 | Vertical connecting element |

### DETAILED DESCRIPTION OF ILLUSTRATIVE EMBODIMENTS

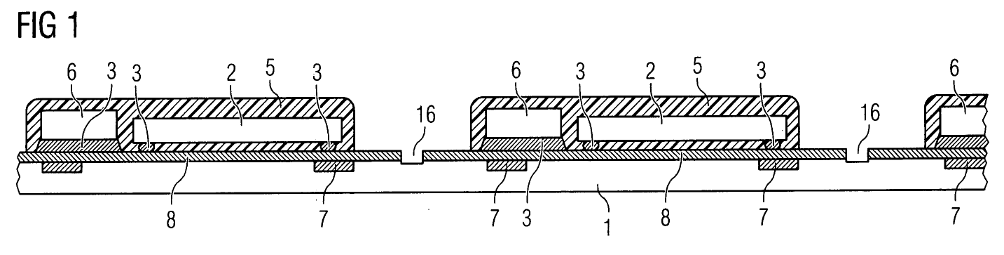

FIG. 1 shows a sectional illustration of a plurality of three-dimensionally integrated electronic assemblies that are arranged alongside one another on a wafer 1 (that is to say individual chips situated alongside one another, in each case, in the wafer assemblage), in the form of an excerpt. For the electrical contact-connection of further components, such as chips 2 and SMD components 6, an RDL 8 is situated on the wafer 1 and is electrically connected to the wafer 1 by means of bonding pads/contact areas 7. The chips 2 and SMD components 6 are, in each case, mounted on the RDL 8 by means of an electrical connection 3 (e.g., solder connection or adhesive-bonding connection).

The abbreviation RDL used here stands for redistribution lines, redistribution layer and/or other interconnects and areas for wiring, in each case comprising an insulator and interconnects. Furthermore, the term wafer is used for chips situated in the wafer assemblage.

Each electronic assembly on the wafer 1 is encapsulated with a molding composition 5, with the result that individual assemblies arise after the singulation of the wafer by sawing along the separating trenches 16.

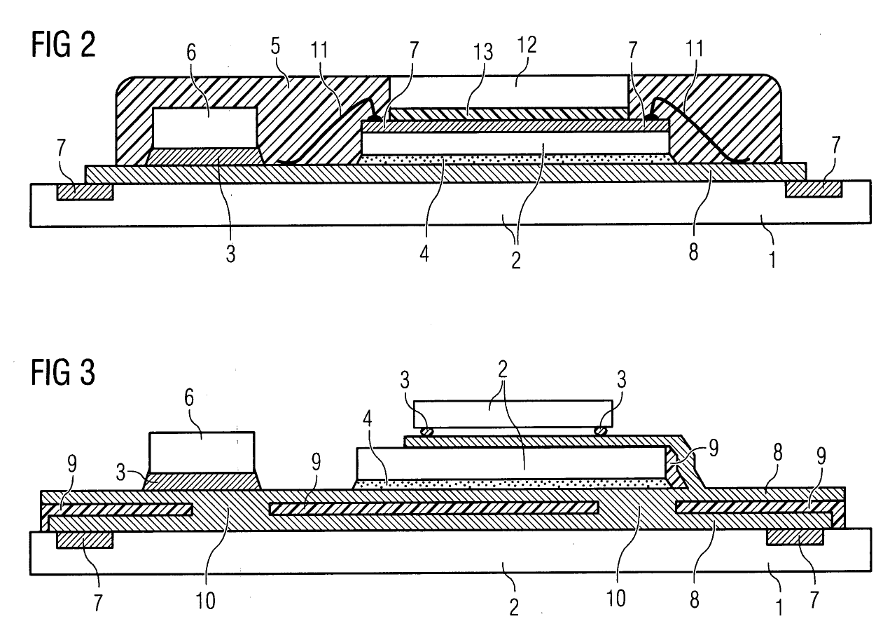

Another embodiment is illustrated in FIG. 2. The latter shows a sectional illustration of an embodiment variant constructed on a substrate 1 (chips in the wafer assemblage, if necessary also singulated chips) with a further chip 2, which is mechanically and electrically connected to the substrate 1 by means of die attach/adhesive film 4 and wire bridges 11, and on which is mounted an additional element 12, e.g., a heat distributor, an optical sensor or the like, with the aid of an electrical, mechanical and/or thermal connecting layer 13. In this case, the wire bridges 11 extend from the bonding pads 7 on the chip 2 onto the RDL 8 on the wafer 1. Furthermore, a further SMD component 6 is mounted on the RDL 8 by means of an electrical connection 3 (e.g., solder connection, adhesive-bonding connection or fusible connection). The electronic assembly is partially encapsulated with a molding composition 5.

FIG. 3 shows a further embodiment with a chip stack arrangement on the wafer 1 with multilayer RDL 8 and with additional RDL 8 between the chips 2. The multilayer (lower) RDL 8 is provided with RDL plated-through holes 10 and electrically connected to bonding pads/contact areas 7 on the wafer 1. An insulator 9 is situated between the layers of the RDL 8. The chip 2 mounted on the RDL 8 by means of a die attach 4 carries, for its part, an RDL 8 on the top side. The RDL 8 is led laterally around the chip 2 onto the lower RDL 8. In order to avoid a short circuit with chip structures, an insulator 9 is arranged between the lateral edge of the chip 2 and the RDL 8.

A further chip 2 is mounted on the RDL 8 of the second chip by means of an electrical connection 3 (e.g., solder connection or adhesive-bonding connection). As in FIG. 2, another SMD component 6 is mounted on the lower RDL 8 by means of an electrical connection 3.

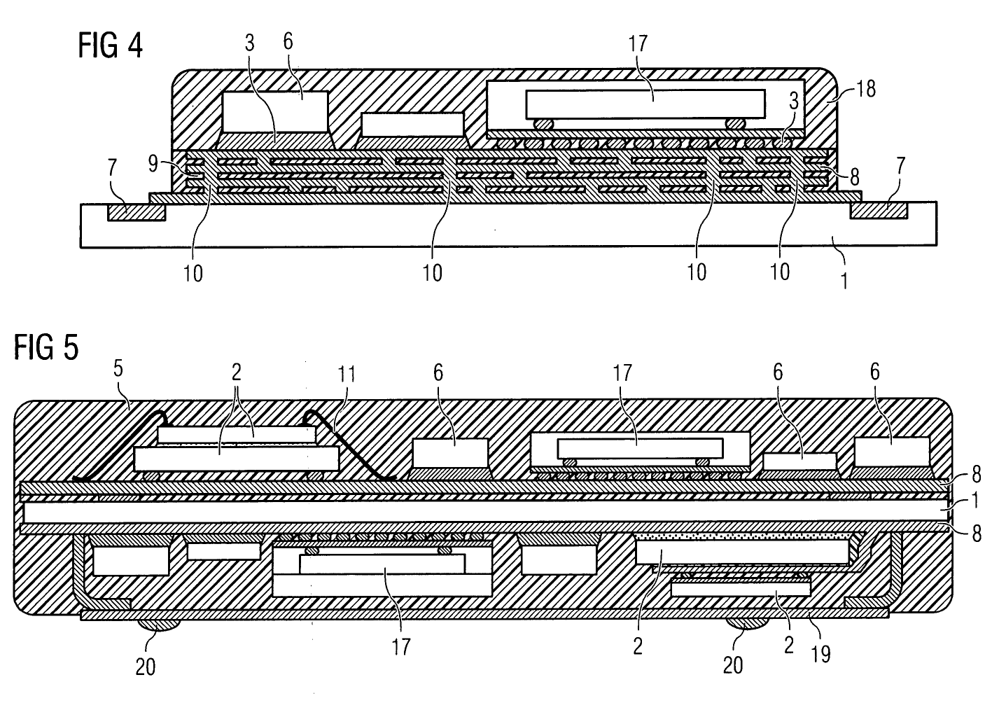

FIG. 4 illustrates a further variant of an RDL chip arrangement on a wafer 1. In this case, there is situated on the wafer a multilayer RDL 8 with insulators 9 between the individual layers and also plated-through holes 10, the bottommost layer of the RDL 8 being connected to the bonding pads 7 of the wafer 1. A BGA component 17 and also further SMD components 6 are mounted on the RDL 8 and contact-connected by means of electrical connections 3. The BGA component 17 is encapsulated with its own encapsulant 18. Instead of the BGA component 17, other components, such as CSP components, may also be mounted as required.

FIG. 5 shows a three-dimensionally integrated electronic assembly on a through-plated wafer 1 with bilateral RDL 8 with a plurality of chips 2, BGA components 17 and SMD components 6 mounted on both sides. The entire arrangement is encapsulated on both sides with a molding composition 5. A PCB 19 (printed circuit board) with contact bumps 20 is provided here for the external contact-connection.

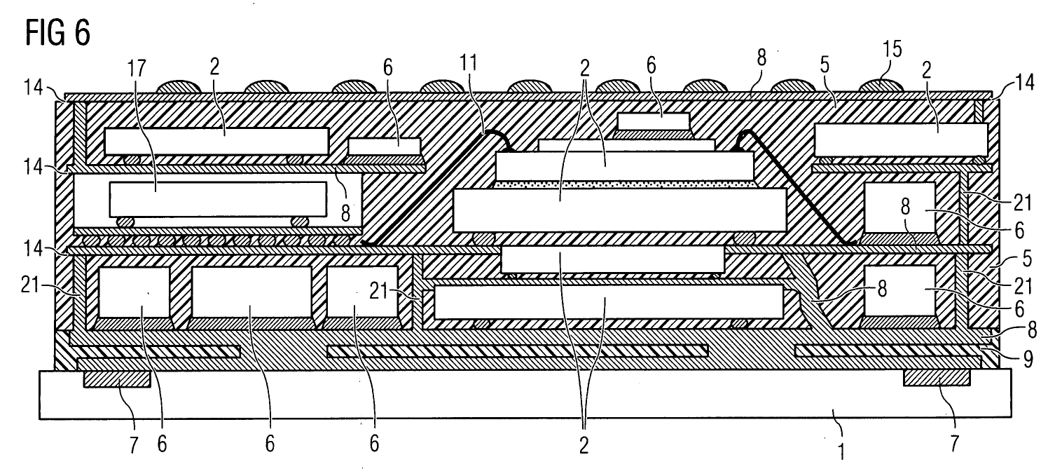

Another embodiment of an integrated electronic assembly is illustrated in FIG. 6. In this case, there is arranged on a wafer 1 firstly a multilayer RDL 8, on which are mounted two chips 2 one above another and a plurality of SMD components 6 alongside the chips. For planarizing this plane, there is situated above it a polymer 14 having vertical connecting elements 21 for electrically connecting the lower multilayer RDL 8 to the RDL 8 of a further, overlying plane. Further components such as a BGA component 17, a stacked arrangement of chips 2 and further SMD components 6 and chips 2 are then mounted on the RDL 8 situated above the polymer 14. Details of the mounting and connecting technology correspond to the technologies already described with regard to the previous figures of the drawings.

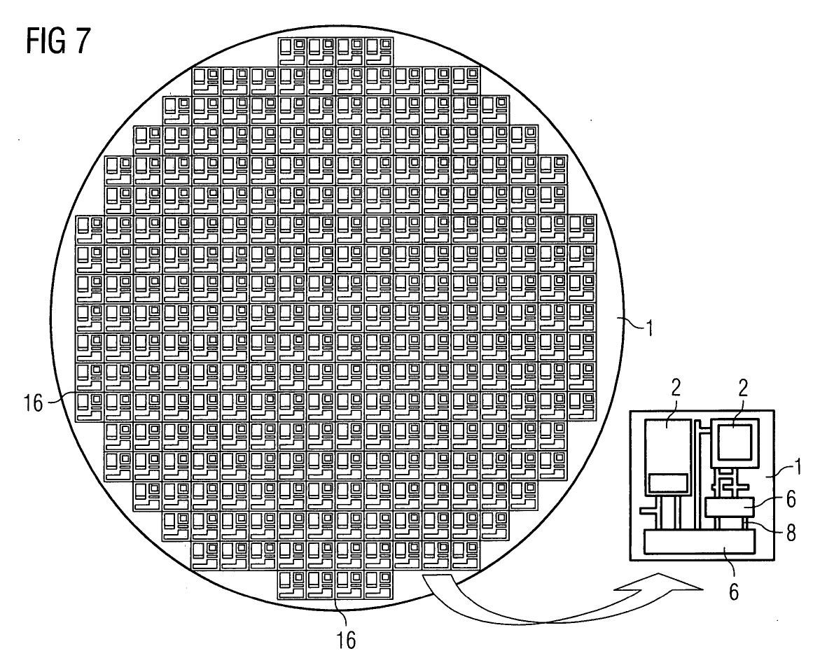

FIG. 7 shows an example of RDL chip arrangements constructed alongside one another on a wafer with chips 2, RDL 8 and further components, such as SMD components 6. The electronic assemblies are fabricated in the wafer assemblage by means of the process steps of wafer processing, testing, if appropriate rear side processing, application of the RDL, mounting of additional chips, active and/or passive elements, molding, planarization and identification. This is followed by the singulation of the electronic assemblies by sawing, for example, and also a concluding functional test.

As discussed above, in one embodiment, a three-dimensionally integrated electronic assembly contains one or a plurality of chips and/or one or a plurality of active and/or passive components or assemblies that are mounted on a substrate and are connected to one another and/or to the substrate. The substrate is an integrated active electronic circuit structure comprising a semiconductor chip at least partly singulated or in the wafer assemblage, a semiconductor wafer, a part of a semiconductor wafer or a plurality of semiconductor wafers mounted one on top of another as second level assembly, a circuit structure on a film or fabric basis and/or on a basis of other inorganic, organic or combined materials with integrated electronic circuit structures embedded, printed on or applied and/or introduced by other methods, forming a plane 1. There are arranged at least on said plane 1 redistribution lines, a redistribution layer and/or further interconnects and areas for wiring (RDL) by means of which one or a plurality of additional chips, active and/or passive components, assemblies or parts thereof are connected and/or contact-connected, forming at least one further plane (plane 2) or a plurality of additional planes 2 . . . n.

What is claimed is:

1. A three-dimensionally integrated electronic assembly, comprising:
a substrate that includes active circuitry formed therein, the substrate defining a first plane;
at least one electronic component mounted on the substrate, the at least one electronic component selected from the group consisting of integrated circuit chips, active components, passive components, active assemblies, and passive assemblies and combinations thereof; and
at least one redistribution connection disposed between the substrate and the at least one electronic component, the at least one redistribution connection defining a second plane spaced from the first plane, wherein the at least one electronic component is electrically coupled to the substrate and/or another electronic component mounted on the substrate by means of the at least one redistribution connection, the at least one redistribution connection comprising a redistribution line, a redistribution layer and/or further interconnects and areas for wiring.

2. The three-dimensionally integrated electronic assembly as claimed in claim 1, wherein the substrate comprises an integrated active electronic circuit structure comprising a semiconductor chip at least partly singulated or in a wafer assemblage, a semiconductor wafer, a part of a semiconductor wafer or a plurality of semiconductor wafers mounted one on top of another as second level assembly, a circuit structure on a film or fabric basis and/or on a basis of other inorganic, organic or combined materials with integrated electronic circuit structures embedded, printed on or applied and/or introduced by other methods

3. The three-dimensionally integrated electronic assembly as claimed in claim 1, wherein the at least one redistribution connection defines a plurality of planes spaced from and substantially parallel to the first plane, the plurality of planes being electrically coupled among one another.

4. The three-dimensionally integrated electronic assembly as claimed in claim 3, wherein the at least one redistribution connection includes plated-through holes between at least one layer.

5. The three-dimensionally integrated electronic assembly as claimed in claim 3, wherein the at least one redistribution connection includes a plane for ground, a plane for a shield, and/or a plane for a supply voltage.

6. The three-dimensionally integrated electronic assembly as claimed in claim 1, wherein the at least one electronic component comprises a plurality of electronic components that are mounted and/or contact-connected on the at least one redistribution connection by bonding, adhesive bonding, welding, soldering, elastomer bumps, electrically conductive adhesive-bonding, and/or wire bridges.

7. The three-dimensionally integrated electronic assembly as claimed in claim 1, wherein the at least one redistribution connection is formed as a waveguide for radio frequency applications.

8. The three-dimensionally integrated electronic assembly as claimed in claim 1, wherein the at least one redistribution connection includes a continuous conductor with a first portion that extends parallel to the first plane and a second portion that extends around edges of the substrate and/or the at least one electronic component.

9. The three-dimensionally integrated electronic assembly as claimed in claim 1, wherein the at least one redistribution connection includes a first conductor and a second conductor, the first conductor spaced from the second conductor by the substrate.

10. The three-dimensionally integrated electronic assembly as claimed in claim 9, wherein the first conductor is electrically connected to the second conductor via plated-through holes through the substrate.

11. The three-dimensionally integrated electronic assembly as claimed in claim 1, wherein the at least one electronic component includes first and second integrated circuit chips and first and second passive components, wherein the first integrated circuit chip and the first passive component are disposed over a top side of the substrate and wherein the second integrated circuit chip and the second passive component are disposed under a bottom side of the substrate.

12. The three-dimensionally integrated electronic assembly as claimed in claim 1, wherein the at least one electronic component comprises at least one component selected from the group consisting of packaged chips, SMD components, resistive elements, capacitors, inductors, diodes, transistors, electrical components, electronic components, magnetic components, electromagnetic components, optical components, micromechanical components, optocouplers, RF couplers, antenna elements, sensors, actuators, operating and indication elements, elements for energy storage and/or conversion, heat distributors, cooling elements, contact pins, contact sockets, force-locking connecting elements, and positively locking connecting elements.

13. The three-dimensionally integrated electronic assembly as claimed in claim 1, further comprising an encapsulant surrounding the at least one electronic component.

14. The three-dimensionally integrated electronic assembly as claimed in claim 1, further comprising external connection contacts electrically coupled to the substrate and/or the at least one electronic component such that the assembly can operate as an independent device, the external connection contacts being selected from the group consisting of contact pins, contact sockets, contact areas, contact bumps, electrical couplers, electronic couplers, magnetic couplers, electromagnetic couplers, optical couplers, thermal couplers and mechanical couplers.

15. A method for producing a three-dimensionally integrated electronic assembly, the method comprising:
providing a wafer, the wafer including a plurality of devices, each device including active circuitry;
mounting a plurality of electronic components on the wafer such that each device is electrically coupled to at least one electronic component;
at least partially encapsulating the electronic components;
testing the devices; and
singulating the devices from the wafer after mounting the electronic components, at least partially encapsulating the electronic components and testing the devices.

16. The method as claimed in claim 15, wherein singulating the devices comprises sawing the wafer.

17. The method as claimed in claim 15, wherein the electronic components comprise components selected from the group consisting of integrated circuit chips, active components, passive components, active assemblies, and passive assemblies and combinations thereof.

18. The method as claimed in claim 17, further comprising planarizing a polymer layer over the substrate prior to mounting the plurality of electronic components.

19. The method as claimed in claim 18, further comprising performing an additional planarization step after mounting the plurality of electronic components.

20. The method as claimed in claim 15, wherein the plurality of electronic components are mounted over a redistribution layer.
